(19) United States
(12) Patent Application Publication
(10) Pub. No.: US 2024/0194775 A1
(43) Pub. Date: Jun. 13, 2024

(54) SEMICONDUCTOR DEVICE

(71) Applicant: Mitsubishi Electric Corporation, Tokyo (JP)

(72) Inventor: Satoshi SUZUKI, Tokyo (JP)

(73) Assignee: Mitsubishi Electric Corporation, Tokyo (JP)

(21) Appl. No.: 18/554,921

(22) PCT Filed: Aug. 24, 2021
(86) PCT No.: PCT/JP2021/030992

§ 371 Date: Oct. 11, 2023

(51) Int. Cl. H01L 29/778; H01L 29/20

(52) U.S. Cl. CPC H01L 29/7786; H01L 29/2003

(57) ABSTRACT

A semiconductor device according to the present disclosure includes a SiC substrate, an AlN nucleation layer provided on the SiC substrate, an AlGaN buffer layer provided on the AlN nucleation layer, a GaN channel layer provided on the AlGaN buffer layer, an AlGaN barrier layer provided on the GaN channel layer and a drain electrode, a source electrode, and a gate electrode each provided above the AlGaN barrier layer, wherein the AlGaN buffer layer has an Al composition ratio decreasing from the SiC substrate toward the GaN channel layer, and a thickness of the AlN nucleation layer is less than or equal to 30 nm.

### FIELD

The present disclosure relates to a semiconductor device.

### BACKGROUND

PTL 1 discloses a multilayered epitaxial film that can be used for a field-effect transistor. This multilayered epitaxial film has a stacked structure in which a junction composed of an electron supply layer and a channel layer is formed on a buffer layer. The buffer layer includes a region formed of a semiconductor material whose composition monotonically changes along a direction from the front surface of a substrate toward the channel layer.

### CITATION LIST

### Patent Literature

[PTL 1] JP 5098649 B

### SUMMARY

### Technical Problem

A field-effect transistor used for a high-frequency power amplifier may be required to have a configuration in which electron mobility is enhanced and a gate length is reduced so as to obtain excellent high-frequency characteristics. For example, in a GaN-based field-effect transistor for a GHz-band high-output power amplifier, a two-dimensional electron gas formed at a GaN/AlGaN hetero-interface may be used and a short-gate structure having a gate length of 1 μm or less may be used so as to obtain high electron mobility. Such a transistor is used in, for example, a fifth-generation mobile communication system.

However, in such a short-gate structure, if a high drain voltage is applied, an electric line of force from the drain extends to a region below the gate, which may lead to a decrease in potential on a substrate side below the gate. This facilitates injection of electrons from the two-dimensional electron gas into the substrate-side buffer layer. Accordingly, deterioration in characteristics may occur due to so-called short-channel effects such as an increase in off-leakage current and a threshold voltage rise. As a countermeasure against this, impurities such as iron or carbon can be added to the buffer layer. These impurities form an acceptor-type deep energy level. This makes it possible to terminate the electric line of force from the drain with negative charges of electrons trapped in an impurity level. Accordingly, short-channel effects upon application of a high drain voltage can be suppressed.

However, for example, in the case of iron, it takes about 100 μs to 100 ms to discharge electrons trapped in the deep energy level. Therefore, if the drain voltage is rapidly changed, it takes a long time for a drain current to reach a steady-state value. Such a time variation of the drain current may have a large influence on signal quality in a wireless communication system based on a linear modulation and time division duplex (TDD) system. Such a wireless communication system is used in, for example, fourth-generation Time Division Long Term Evolution (TD-LTE) or fifth-generation communication systems representative of mobile phone systems.

In the TDD system, about 1000 continuous symbol times of about 100 μs or less form a frame of 10 ms. Accordingly, if the drain current greatly changes within a period of about 100 μs to 10 ms, the gain of the amplifier greatly varies according to the change of the drain current. For example, in 64-value quadrature amplitude modulation (QAM) or 256-value QAM, information is included in the signal amplitude or signal phase. In this case, there is a possibility that an error may occur in the signal amplitude or phase in linear modulation, which may lead to deterioration in signal quality. Thus, if short-channel effects are suppressed by adding impurities, the signal quality may deteriorate.

On the other hand, as a method for suppressing short-channel effects without introducing a deep energy level into the buffer layer, a method of decreasing an Al composition ratio of the buffer layer from the substrate toward the front surface is known as disclosed in PTL 1. In PTL 1, the buffer layer is formed on the substrate through an AlN nucleation layer. In PTL 1, the thickness of the AlN nucleation layer is set in a range of 40 nm to 100 nm. In this case, if an AlGaN buffer layer is applied onto the AlN nucleation layer, the AlN nucleation layer becomes a potential barrier. Thus, there is a possibility that charges at an interface between the AlGaN buffer layer and the AlN nucleation layer and at an interface between the AlN nucleation layer and the substrate may be charged or discharged upon application of a high drain voltage. This may induce a time variation of the drain current.

An object of the present disclosure is to obtain a semiconductor device capable of suppressing a time variation of the drain current.

### Solution to Problem

A semiconductor device according to the present disclosure includes a SiC substrate, an AlN nucleation layer provided on the SiC substrate, an AlGaN buffer layer provided on the AlN nucleation layer, a GaN channel layer provided on the AlGaN buffer layer, an AlGaN barrier layer provided on the GaN channel layer and a drain electrode, a source electrode, and a gate electrode each provided above the AlGaN barrier layer, wherein the AlGaN buffer layer has an Al composition ratio decreasing from the SiC substrate toward the GaN channel layer, and a thickness of the AlN nucleation layer is less than or equal to 30 nm.

### Advantageous Effects of Invention

In the semiconductor device according to the present disclosure, the thickness of the AlN nucleation layer is less than or equal to 30 nm. Accordingly, a time variation of the drain current can be suppressed.

### BRIEF DESCRIPTION OF DRAWINGS

FIG. 1 is a sectional view of a semiconductor device according to the first embodiment.

FIG. 2 is a sectional view of a semiconductor device according to a comparative example.

FIG. 3 is a graph illustrating effects of the modulation of the Al composition ratio on short-channel effects.

FIG. 4 is a sectional view when an interval between the source electrode and the drain electrode is large in the semiconductor device according to the comparative example.

FIG. 5 is a sectional view when the interval between the source electrode and the drain electrode is small in the semiconductor device according to the comparative example.

FIG. 6 is a sectional view when the interval between the source electrode and the drain electrode is large in the semiconductor device according to the first embodiment.

FIG. 7 is a sectional view when the interval between the source electrode and the drain electrode is small in the semiconductor device according to the first embodiment.

FIG. 8 is a graph illustrating a change of current due to a back-surface electrode voltage in the semiconductor device according to the comparative example.

FIG. 9 is a graph illustrating a change of current due to the back-surface electrode voltage in the semiconductor device according to the first embodiment.

FIG. 10 is a graph illustrating a relationship between the thickness of the AlN nucleation layer and the current value.

FIG. 11 is an energy band diagram from the front surface of a semiconductor layer to a depth of 100 μm.

FIG. 12 is an energy band diagram from the front surface of the semiconductor layer to a depth of 4 μm.

FIG. 13 is a graph illustrating a variation of the drain current in the semiconductor device according to the comparative example.

FIG. 14 is a graph illustrating a variation of the drain current in the semiconductor device according to the first embodiment.

### DESCRIPTION OF EMBODIMENTS

The semiconductor device according to the embodiment is described with reference to drawings. Identical or corresponding constitutional elements are given the same reference numerals, and the repeated description of such constitutional elements may be omitted.

### First Embodiment

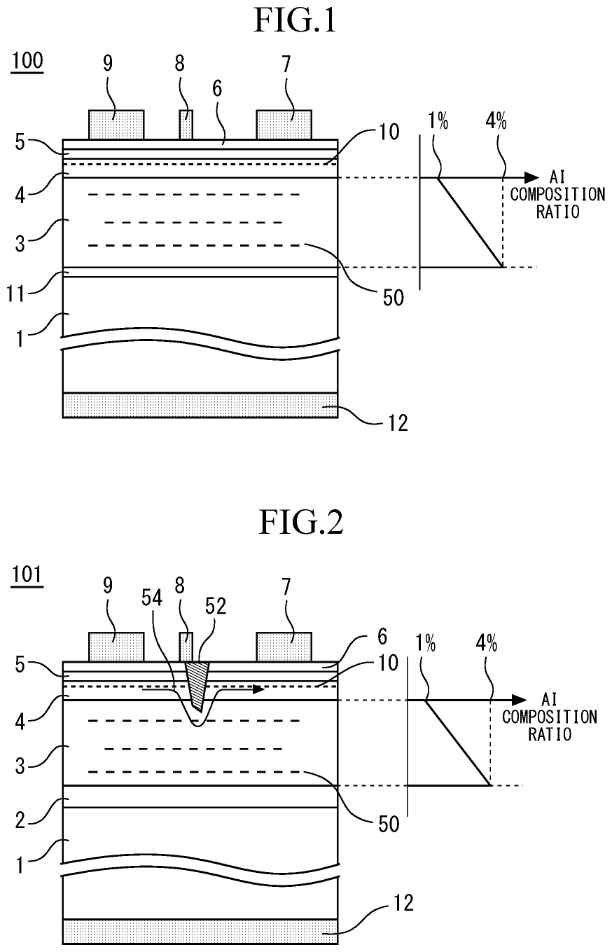

FIG. 1 is a sectional view of a semiconductor device 100 according to a first embodiment. The semiconductor device 100 is a field-effect transistor having a GaN/AlGaN hetero-interface. The semiconductor device 100 includes a substrate 1. The substrate 1 is formed of, for example, semi-insulating SiC. The thickness of the substrate 1 is, for example, 100 μm, and the top surface of the substrate is, for example, a (0001) surface.

An AlN nucleation layer 11 is provided on the substrate 1. The AlN nucleation layer 11 is formed with a small thickness so that an electrical resistance in a stacking direction can be reduced. The thickness of the AlN nucleation layer 11 is, for example, 10 nm. As described below, the thickness of the AlN nucleation layer 11 is preferably less than or equal to 30 nm.

An AlGaN buffer layer 3 is provided on the AlN nucleation layer 11. An Al composition ratio of the AlGaN buffer layer 3 is modulated. As illustrated in a graph in FIG. 1, the Al composition ratio of the AlGaN buffer layer 3 decreases from the substrate 1 toward a GaN channel layer 4. In FIG. 1, the Al composition ratio decreases from 4% to 1%. The value of the Al composition ratio is not limited to this value. As described below, a maximum value of the Al composition ratio of the AlGaN buffer layer 3 is preferably less than or equal to 10%. The thickness of the AlGaN buffer layer 3 is, for example, 300 nm. Note that the sign “−” in the AlGaN buffer layer 3 represents negative space charges 50 introduced by modulating the Al composition ratio.

The undoped GaN channel layer 4 is provided on the AlGaN buffer layer 3. The thickness of the GaN channel layer 4 is, for example, 100 nm. An undoped AlGaN barrier layer 5 is provided on the GaN channel layer 4. The AlGaN barrier layer 5 has a thickness of, for example, 20 nm, and has an Al composition ratio of, for example, 25%. A two-dimensional electron gas 10 is formed at an interface between the GaN channel layer 4 and the AlGaN barrier layer 5. A GaN cap layer 6 is provided on the AlGaN barrier layer 5. The thickness of the GaN cap layer 6 is, for example, 2 nm.

A drain electrode 7, a source electrode 9, and a gate electrode 8 are provided on the GaN cap layer 6. A back-surface electrode 12 is formed on the back surface of the substrate 1.

FIG. 2 is a sectional view of a semiconductor device 101 according to a comparative example. The thickness of the AlN nucleation layer in the semiconductor device 101 according to the comparative example is different from that in the semiconductor device 100 according to the present embodiment. In the semiconductor device 101, the thickness of the AlN nucleation layer 2 is 60 nm. FIG. 2 illustrates an electron depletion region 52 upon application of a high drain voltage. FIG. 2 also illustrates a path 54 for electrons that are injected from the two-dimensional electron gas 10 into the AlGaN buffer layer 3 upon application of a high drain voltage and reach the drain.

Next, the effect of the AlGaN buffer layer 3 in which the Al composition ratio is modulated in the stacking direction is described. In a short-gate structure, when a high drain voltage is applied, a potential on the side of the substrate 1 is decreased. In this case, electrons are injected into the AlGaN buffer layer 3 from the two-dimensional electron gas 10 on the path 54 along the electron depletion region 52 formed over the area from the gate to the drain. The electrons become a leakage current to reach the drain.

To prevent the electrons from being injected into the AlGaN buffer layer 3, it may be desirable to form the negative space charges 50 in the AlGaN buffer layer 3 to enhance the entrapment of electrons to the channel side. GaN and AlN include spontaneous polarization and piezoelectric properties. The amount of polarized charge in AlGaN as a mixed crystal of these compounds varies depending on a composition ratio between Al and Ga as Group III elements. Accordingly, two-dimensionally distributed polarized charges are three-dimensionally distributed by changing the Al composition ratio in an epitaxial stacking direction, thereby making it possible to induce the space charges 50. When the drain voltage is 50 V, the negative space charges 50 that are required to suppress short-channel effects are converted into a volume density of about 5×10¹⁶ cm⁻³.

Thus, the Al composition ratio of the AlGaN buffer layer 3 is decreased toward the GaN channel layer 4, thereby making it possible to form the negative space charges 50 in the AlGaN buffer layer 3. This can enhance the entrapment of electrons to the channel side. Accordingly, upon application of a high drain voltage, the injection of electrons from the two-dimensional electron gas 10 into the side of the substrate 1 can be suppressed.

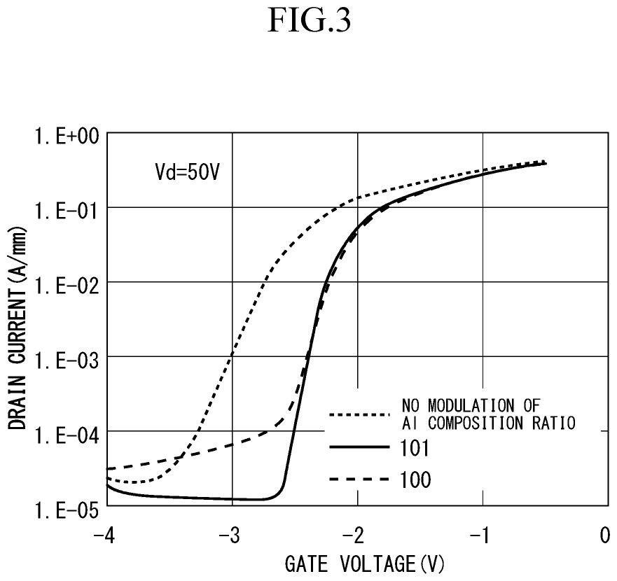

FIG. 3 is a graph illustrating effects of the modulation of the Al composition ratio on short-channel effects. FIG. 3 illustrates the dependence of the drain current on a gate voltage in each of a structure in which the Al composition ratio of the AlGaN buffer layer 3 is not modulated and the semiconductor devices 100 and 101. In FIG. 3, the drain voltage is 50 V. Note that in each of the semiconductor devices 100 and 101, doping of Fe into the AlGaN buffer layer 3 is not carried out.

Unlike in the structure in which the Al composition ratio is not modulated, in the semiconductor devices 100 and 101 in which the Al composition ratio is modulated, the drain current is rapidly turned off by the gate voltage. In other words, the short-channel effects are suppressed.

When the gate voltage is less than or equal to −2.5 V, the semiconductor device 101 according to the comparative example has a less leakage current than that in the semiconductor device 100 according to the present embodiment. This is because electrons are accumulated on the side of the substrate 1 and the channel is closed from the back surface side in the semiconductor device 101. However, it is considered that the accumulation of electrons on the side of the substrate 1 causes a variation of the drain current as described below.

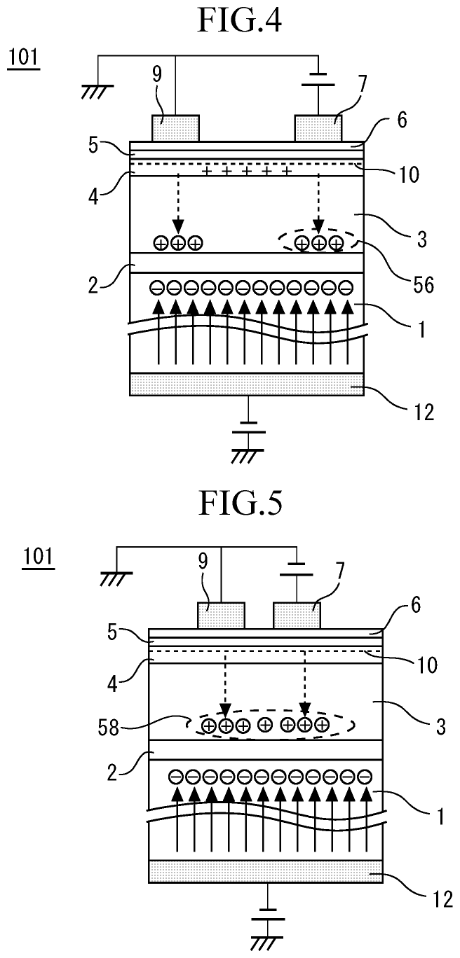

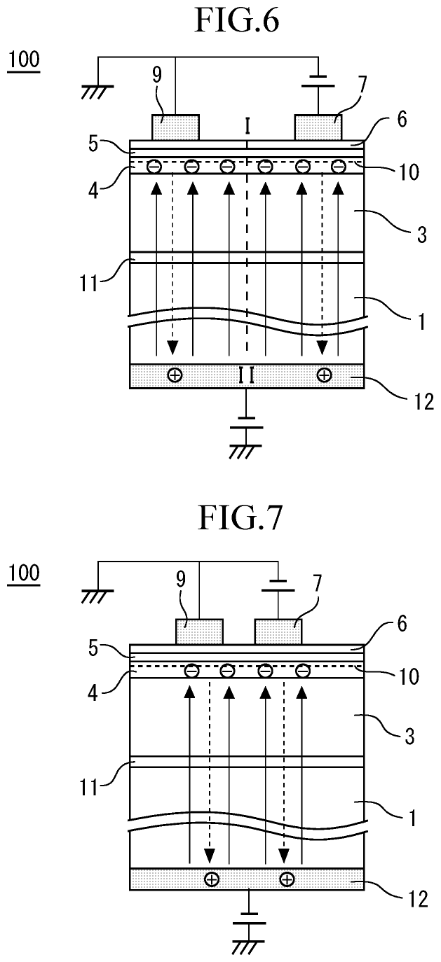

Next, the effect of the thin AlN nucleation layer 11 according to the present embodiment is described. FIG. 4 is a sectional view when an interval between the source electrode and the drain electrode is large in the semiconductor device 101 according to the comparative example. FIG. 5 is a sectional view when the interval between the source electrode and the drain electrode is small in the semiconductor device 101 according to the comparative example. FIG. 6 is a sectional view when the interval between the source electrode and the drain electrode is large in the semiconductor device 100 according to the first embodiment. FIG. 7 is a sectional view when the interval between the source electrode and the drain electrode is small in the semiconductor device 100 according to the first embodiment. In FIGS. 4 to 7, the illustration of the gate electrode 8 is omitted.

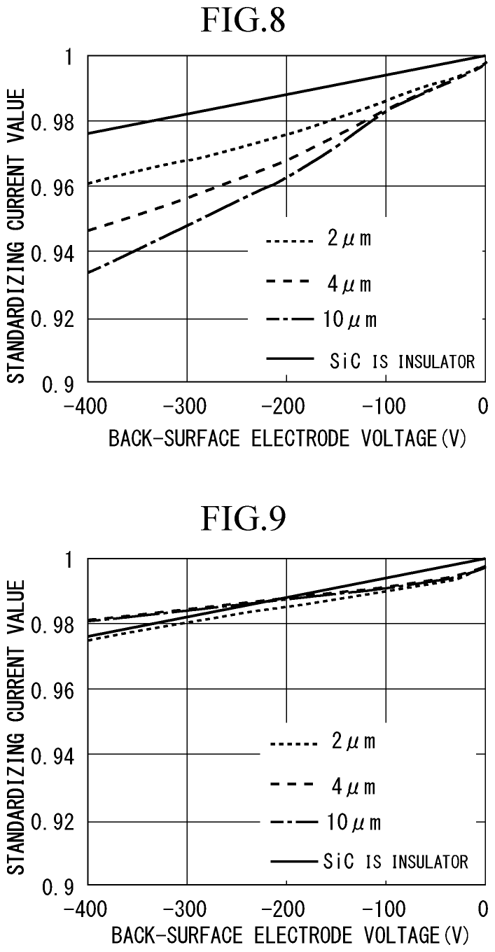

FIG. 8 is a graph illustrating a change of current due to a back-surface electrode voltage in the semiconductor device 101 according to the comparative example. FIG. 9 is a graph illustrating a change of current due to the back-surface electrode voltage in the semiconductor device 100 according to the first embodiment. A method for measuring current values illustrated in FIGS. 8 and 9 is described. First, the value of current flowing through each of the semiconductor devices 100 and 101 is measured by applying 0 V to the back-surface electrode 12, applying 0 V to the source electrode 9, and applying 1 V to the drain electrode 7. This value is set as an initial value. Next, a change of the value of current flowing between the source electrode and the drain electrode when a voltage in a range of 0 V to −400 V is applied to the back-surface electrode 12 at a sweep rate of 10 V/s is measured.

FIG. 8 illustrates values obtained by standardizing current values measured for the semiconductor device 101 illustrated in FIGS. 4 and 5 with the initial value. Similarly, FIG. 9 illustrates values obtained by standardizing current values measured for the semiconductor device 100 illustrated in FIGS. 6 and 7 with the initial value. A solid line in FIGS. 8 and 9 indicates the calculated value of a current change when no charges are accumulated at the interface in each layer, assuming that an epitaxial layer and a SiC substrate are insulators. This calculated value is hereinafter referred to as an ideal value.

As illustrated in FIG. 8, in the semiconductor device 101 according to the comparative example, the current value is dependent on a negative voltage on the back surface and is smaller than the ideal value. This is considered to be because, as illustrated in FIGS. 4 and 5, electrons injected from the back-surface electrode 12 due to a large negative voltage on the back surface reach an area near the interface between the substrate 1 and the epitaxial layer and are accumulated. In other words, an electric field of the accumulated electrons decreases the two-dimensional electron gas 10, so that the current value decreases.

On the other hand, as illustrated in FIG. 9, in the semiconductor device 100 according to the present embodiment, the current value is close to the ideal value. This is considered to be because the thin AlN nucleation layer 11 has a low potential barrier and a smaller number of electrons are accumulated as illustrated in FIGS. 6 and 7.

Further, as illustrated in FIG. 8, in the semiconductor device 101, the negative voltage on the back surface has less influence as a distance between the source electrode and the drain electrode decreases. This configuration is described. As illustrated in FIG. 4, holes 56 injected from the drain are accumulated on the side of the AlGaN buffer layer 3 that is closer to the substrate 1. When the interval between the electrodes is large as illustrated in FIG. 4, a leak path is less likely to be formed, and thus the accumulated holes 56 have less influence. In this case, the electric field of electrons accumulated in the vicinity of the interface between the substrate 1 and the epitaxial layer decreases the current. On the other hand, when the interval between the electrodes is small as illustrated in FIG. 5, a hole leak path 58 is more likely to be formed. It is considered that this leak path 58 blocks the electric field from the accumulated electrons, so that the amount of decrease of the current is small.

The hole leak path 58 can also be formed between adjacent semiconductor devices. Accordingly, in a multi-finger field-effect transistor having a configuration in which a plurality of transistors is arranged, a drain voltage applied to a certain transistor may modulate a drain current of another transistor adjacent to the transistor. On the other hand, as illustrated in FIG. 9, the dependence of the current value in the semiconductor device 100 according to the present embodiment on the interval between electrodes is small. Accordingly, not only the number of accumulated electrons, but also the number of accumulated holes is considered to be small. For this reason, the modulation of the drain current can be suppressed by applying the semiconductor device 100 according to the present embodiment to the multi-finger field-effect transistor.

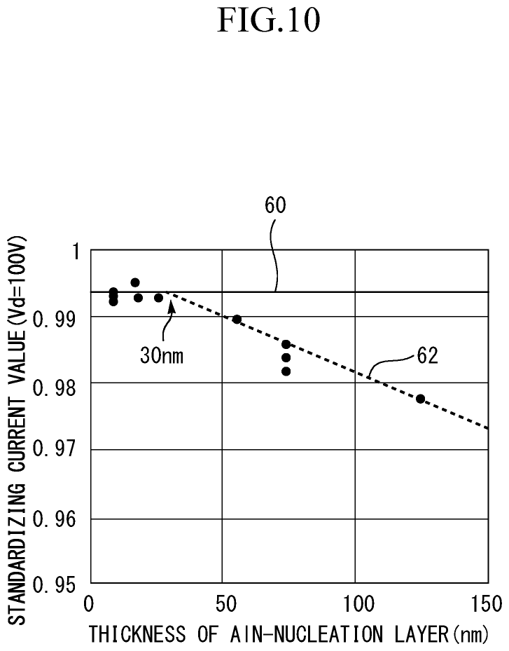

FIG. 10 is a graph illustrating a relationship between the thickness of the AlN nucleation layer and the current value. The thickness of the AlN nucleation layer in which charges are accumulated at the interface between the AlGaN buffer layer 3 and the AlN nucleation layer and at the interface between the AlN nucleation layer and the substrate 1 was experimentally confirmed. The semiconductor device 100 having the structure illustrated in FIG. 6 was used in experiments. In the experiments, the value of the current flowing between the source and the drain was measured for each of the AlN nucleation layers having thicknesses of 10, 20, 25, 60, 75, and 125 nm, respectively. FIG. 10 illustrates values obtained by standardizing current values obtained by applying −100 V to the back-surface electrode 12, applying 0 V to the source electrode 9, and applying 1 V to the drain electrode 7 with current values obtained by applying 0 V to the back-surface electrode 12, applying 0 V to the source electrode 9, and applying 1 V to the drain electrode 7.

When the AlN nucleation layer 11 has a thickness in a range of 10 nm to 25 nm, the amount of decrease of the current when −100 V is applied to the back-surface electrode is substantially zero. In this case, the standardized current value is substantially equal to the value when it is assumed that the substrate 1 is an insulator, as indicated by a solid line 60. When the thickness of the AlN nucleation layer is more than 60 nm, the amount of decrease of the current when −100 V is applied to the back-surface electrode 12 increases depending on the thickness of the AlN nucleation layer. Based on an extrapolation value obtained using a broken line 62 illustrated in FIG. 10, it can be estimated that a thickness of 30 nm or less is suitable as the thickness of the AlN nucleation layer 11 in which electrons are prevented from being accumulated.

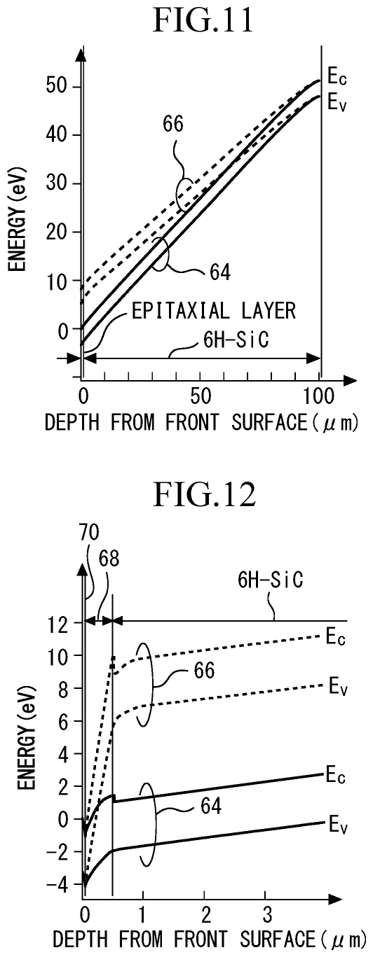

Next, a preferable value as the Al composition ratio of the AlGaN buffer layer 3 is described. FIG. 11 is an energy band diagram from the front surface of a semiconductor layer to a depth of 100 μm. FIG. 12 is an energy band diagram from the front surface of the semiconductor layer to a depth of 4 μm. FIGS. 11 and 12 illustrate calculated values of the energy band diagram taken along a line I-II when −50 V is applied to the back-surface electrode 12, 0 V is applied to the source electrode 9, and 1 V is applied to the drain electrode 7 in the structure of FIG. 6. In the calculation, the AlN nucleation layer 11 that is a low-resistance layer is omitted.

In FIGS. 11 and 12, a solid line 64 indicates a case where a maximum value of the Al composition ratio of the AlGaN buffer layer 3 is 10%, and a broken line 66 indicates a case where the maximum value is 50%. In FIG. 12, a region 68 corresponds to the AlGaN buffer layer 3 and the GaN channel layer 4, and a region 70 corresponds to the AlGaN barrier layer 5 and the GaN cap layer 6.

When the Al composition ratio is 10%, most of the voltage of 50 V drops at the substrate 1, and a large voltage is not applied to the epitaxial layer. When the Al composition ratio is 50%, a large voltage is applied to the epitaxial layer. This configuration is described. As the Al composition ratio in AlGaN increases, the difference between a conduction band edge and a vacuum level, that is, electron affinity decreases. Accordingly, the band discontinuity at the conduction band edge between AlGaN and SiC becomes a large potential barrier against electrons flowing in from the back-surface electrode 12, so that electrons can be easily accumulated at the interface between the AlGaN buffer layer 3 and the substrate 1. It is considered that the accumulation of electrons causes an electric field in the epitaxial layer.

Thus, if the Al composition ratio of the AlGaN buffer layer 3 is large, even when the thin AlN nucleation layer 11 according to the present embodiment is used, electrons may be accumulated in the vicinity of the interface between the AlGaN buffer layer 3 and the substrate 1 due to the band discontinuity at the conduction band edge. In this case, the drain current may be undesirably modulated. Therefore, the sufficient effect of entrapping the two-dimensional electron gas 10 can be obtained by setting the maximum value of the Al composition ratio of the AlGaN buffer layer 3 to be less than or equal to 10%. The conduction band discontinuity between the AlGaN buffer layer 3 and the substrate 1 is about 0.3 eV when the Al composition ratio is 10%, and is sufficiently smaller than 1.6 eV when the Al composition ratio is 50%.

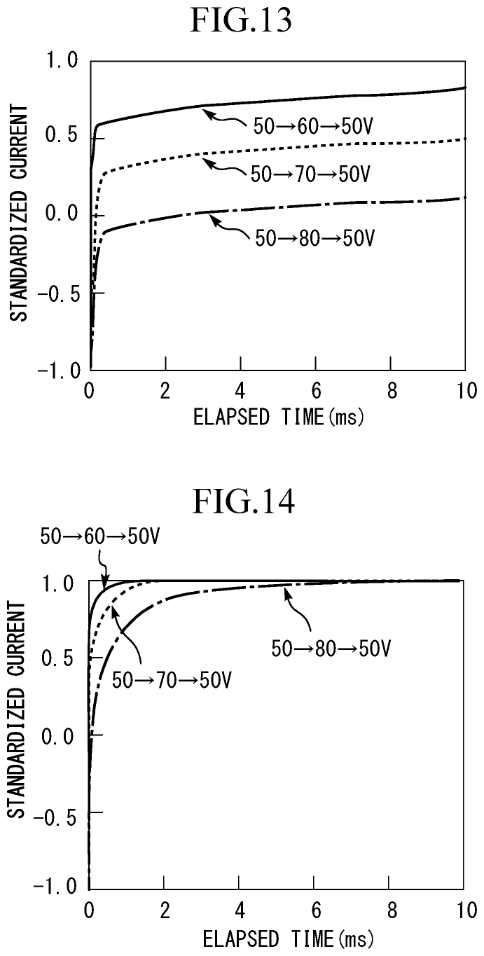

FIG. 13 is a graph illustrating a variation of the drain current in the semiconductor device 101 according to the comparative example. FIG. 13 assumes a structure in which the AlGaN buffer layer 3 whose Al composition ratio is 4% at a maximum and decreases from the side of the substrate 1 toward the front surface is stacked on the AlN nucleation layer 2 having a thickness of 60 nm. FIG. 14 is a graph illustrating a variation of the drain current in the semiconductor device 100 according to the first embodiment. FIG. 14 assumes a structure in which the AlGaN buffer layer 3 whose Al composition ratio is 4% at a maximum and decreases from the side of the substrate 1 to the front surface is stacked on the AlN nucleation layer 11 having a thickness of 10 nm.

A time variation of the drain current is evaluated by the following method. First, the drain voltage of 50 V is applied and the gate voltage is adjusted such that the drain current value is about 1/10 when the gate voltage of 0 V is applied. The drain current value obtained in this time is referred to as an initial value. Next, the drain voltage is instantaneously boosted and held for 100 μs. The step-up value of the drain voltage is one of 60 V, 70 V, and 80 V. After that, the drain voltage is returned to 50 V with a fall time of 0.1 μs, and then a time change of the drain current value is measured. FIGS. 13 and 14 illustrate current values when the step-up values of the drain voltage are 60 V, 70 V, and 80 V. The drain current values in FIGS. 13 and 14 are standardized with the initial value.

As illustrated in FIG. 13, in the semiconductor device 101 according to the comparative example, the drain current value is not returned to the initial value even after a lapse of 10 ms after the drain voltage has changed. Additionally, the amount of change of the drain current increases depending on the amount of change of the drain voltage. On the other hand, in the semiconductor device 100 according to the present embodiment, as illustrated in FIG. 14, the drain current value is recovered to a value close to 90% of the initial value after a lapse of 3 ms. The dependence of the amount of change of the drain current on the amount of change of the drain voltage is also small. Thus, in the present embodiment, the time variation of the drain current can be suppressed.

As described above, the inventor of the present disclosure has found that a time variation of the drain current occurs in the semiconductor device 101 according to the comparative example even when the deep energy level is not introduced into the buffer layer. In general, when a transistor is used as a high-frequency amplifier, a back-surface electrode is formed on the back surface of a substrate and the back-surface electrode is grounded and used. When a drain voltage is applied to the semiconductor device 101, the most part of the voltage to be applied to the back-surface electrode 12 and the drain electrode 7 is applied to the high-resistance AlN nucleation layer 2. As a result, holes injected from the drain electrode 7 are charged or discharged at the interface between the AlGaN buffer layer 3 and the AlN nucleation layer 2 and electrons injected from the back-surface electrode 12 are charged or discharged at the interface between the AlN nucleation layer 2 and the substrate 1 according to the change of the drain voltage. It is considered that the electric field generated from these charges modulates the drain current.

On the other hand, in the present embodiment, the use of the AlN nucleation layer 11 formed with an extremely small thickness to reduce the electrical resistance makes it possible to suppress the voltage to be applied to the AlN nucleation layer 11. Accordingly, this makes it possible to prevent the charges from being charged or discharged at the interface between the AlGaN buffer layer 3 and the AlN nucleation layer 11 and at the interface between the AlN nucleation layer 11 and the substrate 1. Consequently, the time variation of the drain current can be suppressed.

In general, when GaN or AlGaN is grown on a SiC substrate, the AlN nucleation layer is first grown to enhance the wettability of the epitaxial layer with respect to the SiC substrate. At the initial stage of growth of the AlN nucleation layer, the nucleus of AlN is formed in an island shape. This nucleus is referred to as a three-dimensional island. As the growth progresses, three-dimensional islands are joined together and AlN grows in layers. This layered AlN is referred to as a two-dimensional island. Thus, in the growth process, the three-dimensional island and the two-dimensional island coexist. In this case, the density of threading dislocation that is a crystal defect is high. The threading dislocation has such properties that electricity is allowed to pass in the stacking direction of the epitaxial layer. Accordingly, it is considered that the extremely thin AlN nucleation layer at the growth initial stage has a low electrical resistance in the stacking direction.

In the present embodiment, the AlN nucleation layer 11 having a small thickness and a low electrical resistance is formed by actively utilizing this phenomenon. The AlGaN buffer layer 3 is stacked on the AlN nucleation layer 11 formed with an extremely small thickness on the substrate 1, thereby making it possible to suppress the potential barrier between the AlGaN buffer layer 3 and the substrate 1. Therefore, the charges can be prevented from being charged or discharged at the interface between the AlGaN buffer layer 3 and the AlN nucleation layer 11 and at the interface between the AlN nucleation layer 11 and the substrate 1, and the time variation of the drain current can be suppressed.

The Al composition ratio of the AlGaN buffer layer 3 linearly changes with respect to the depth in the graph of FIG. 1, but may not linearly change.

Note that the technical features described in this embodiment may be combined as appropriate.

### REFERENCE SIGNS LIST

1 substrate, 2 AlN nucleation layer, 3 AlGaN buffer layer, 4 GaN channel layer, 5 AlGaN barrier layer, 6 GaN cap layer, 7 drain electrode, 8 gate electrode, 9 source electrode, 11 AlN nucleation layer, 12 back-surface electrode, 50 space charge, 52 depletion region, 54 path, 56 hole, 58 leak path, 100, 101 semiconductor device

1. A semiconductor device comprising:
a SiC substrate;
an AlN nucleation layer provided on the SiC substrate;
an AlGaN buffer layer provided on the AlN nucleation layer;
a GaN channel layer provided on the AlGaN buffer layer;
an AlGaN barrier layer provided on the GaN channel layer; and
a drain electrode, a source electrode, and a gate electrode each provided above the AlGaN barrier layer, wherein
the AlGaN buffer layer has an Al composition ratio decreasing from the SiC substrate toward the GaN channel layer, and
a thickness of the AlN nucleation layer is less than or equal to 30 nm.

2. The semiconductor device according to claim 1, wherein a maximum value of the Al composition ratio of the AlGaN buffer layer is less than or equal to 10%.

3. The semiconductor device according to claim 1, wherein the SiC substrate has semi-insulating properties.

4. The semiconductor device according to claim 2, wherein the SiC substrate has semi-insulating properties.
